(19) United States
(12) Patent Application Publication
(10) Pub. No.: US 2005/0158152 A1
(43) Pub. Date: Jul. 21, 2005

(54) Container conveying system

(76) Inventor: Tetsunori Otaguro, Shinagawa-ku (JP)

Correspondence Address: Lorusso Loud & Kelly, 3137 Mount Vernon Avenue, Alexandria, VA, 22305, US

(21) Appl. No.: 10/516,824

(22) PCT Filed: Jan. 14, 2003
(86) PCT No.: PCT/JP03/00223

(30) Foreign Application Priority Data
Jun. 7, 2002 (JP) 2002-166541

(51) Int. Cl. H01L 21/68; B65G 49/07; B65G 47/00; B65G 1/00

(52) U.S. Cl. 414/217

(57) ABSTRACT

A container conveying system for conveying containers 8 containing substrates such as wafers within a clean room comprises a conveyance apparatus 7 disposed substantially in parallel with plural treatment apparatuses 5-1, 5-2, 5-3, . . . to convey the containers 8 and a transfer apparatus 9 capable of moving freely in an upper ceiling space within the clean room, characterized in that the plural treatment apparatuses 5-1, 5-2, 5-3, . . . are arranged on at least one side of a passage and respectively provided with interface devices 6-1, 6-2, 6-3, . . . on the side facing the passage; the interface devices 6-1, 6-2, 6-3, . . . are capable of temporarily receiving the containers 8 and moving the substrates from the interiors of the containers to the interiors of the treatment apparatuses 5-1, 5-2, 5-3, . . . and vice versa in a hermetically sealed atmosphere; and the transfer apparatus 9 delivers and receives the containers 8 between the conveyance apparatus 7 and the treatment apparatuses 5-1, 5-2, 5-3, . . . or between the treatment apparatuses 5-1, 5-2, 5-3, . . . According to this container conveying system, the container conveying capacity, the treatment capacity, the footprint, the container stock function and the sorting function are further improved.

### TECHNICAL FIELD

The present invention relates to a container conveying system and more particularly to an improvement of a container conveying system capable of freely conveying containers such as FOUP or SMIF pods which contain substrates such as semiconductor wafers, reticles, or glass substrates between plural treatment apparatuses or between plural treatment apparatuses and a conveying apparatus in a manufacturing factory for the manufacture of semiconductor devices or liquid crystal devices.

### BACKGROUND ART

In a manufacturing process for the manufacture of semiconductor integrated circuits or liquid crystal display panels, the product yield is reduced due to adhesion of dusts or particles to such substrates as wafers, reticles, or glass substrates. To avoid this inconvenience, an intra-clean room production line operates and various improvements are made for container conveying equipment and systems which can convey containers freely among various treatment apparatuses installed within the clean room.

The applicant of the present invention has previously invented and filed a patent application for a container conveying equipment having a moving means which can three-dimensionally move a container holding means for holding containers in an upper ceiling space within the clean room (Japanese Patent Application No. 2001-283407).

In this container conveying equipment, a pair of fixed horizontal guide rails are laid in parallel within the ceiling space, and one or plural horizontal travel guide rail or rails are laid between the pair of fixed guide rails so that the travel guide rails can travel along the fixed guide rails. Further, a traveling member traveling along the travel guide rail(s) is provided in the travel guide rail(s). A horizontal moving means is constituted by those fixed guide rails, travel guide rail(s), and the traveling member. A lift means which can raise, lower and rotate the container holding means is provided in the traveling body. A three-dimensional moving means is constituted by the lift means and the horizontal moving means.

In this container conveying equipment, the upper ceiling space within the clean room is utilized as an area for the conveyance of containers and thus the internal space of the clean room can be utilized effectively. Therefore, for the same equipment, a required volume of the clean room can be made small and hence it is possible to reduce equipment cost and maintenance cost for the clean room. Moreover, since the container holding means can be moved linearly from a certain position to another position, a container conveying efficiency can be improved.

Further, in the container conveying equipment in question, the lift means is constituted by an articulated arm having plural arms. Each of the plural arms is successively and alternately superimposed and coupled together at end portions of the arms. The articulated arm extends and retracts with pivotal motions of the constituent arms. Therefore, there is no fear of dislocation of the center of gravity of the articulated arm and the weight balance of the entire arm becomes stable. Even when the articulated arm extends (the lift means descends), there is little deflection caused by gravity. Consequently, the container holding means can deliver containers to the treatment apparatuses without positional deviation. For horizontal conveyance of the containers, the lift means can be folded compactly and disturbance of an air current can be kept to a minimum. Various outstanding effects as mentioned above can be attained.

As a further improvement over the previous invention referred to above, the applicant of the present invention has also invented and applied for patent an improved container conveying system with a view to making a further improvement in the conveyance efficiency, functional properties, space saving, and safety of container conveying apparatuses (Japanese Patent Application No. 2002-111227).

Since this improved container conveying system which is an overhead traveling type is provided with plural container holding means, both loading and unloading of containers can be done in a short time, whereby the container conveyance efficiency is further improved and the production efficiency of the intra-clean room production line can be greatly improved.

Besides, since the lift means is constituted by a telescopic type extension/retraction mechanism and a rotating mechanism for rotating the container holding means is provided at a lower end portion of the extension/ retraction mechanism, a lift mechanism section is simplified and the installation space is saved, whereby a short-distance conveyance of containers becomes possible and it is possible to attain a further reduction of space and cost in the intra-clean room conveyance. Moreover, with the rotating mechanism for the container holding means, the containers can be fed and loaded in any direction and it is possible to take out the containers placed in any direction. Also from this point, the container conveyance efficiency is improved.

Further, a shelf for resting the containers thereon is disposed above a worker passage within a work area of the container conveying system and, if necessary, a sorter for sorting intra-container substrates and a safety net which is cut out only in its portion for access to the treatment apparatuses. Thus, such functions as container stock function, buffer function, and intra-container substrates sorting function, are ensured and it is possible to further improve the container conveyance efficiency and space saving. It is also possible to ensure a sufficient safety of workers. Various excellent effects as mentioned above can be attained.

### DISCLOSURE OF THE INVENTION

However, none of the above conveyance means can yet be said as satisfactory in terms of conveyance capacity and treatment capacity. The first problem resides in the conveyance capacity in long-distance conveyance. In all of the above conveyance means, the degree of freedom is large and the delivery of containers to the plural treatment apparatuses can be done by one and the same conveyance apparatus or system. However, a long time may be taken in case of a longer transfer distance.

The second problem is that in a conveyance system constituted by a single conveyance apparatus, even if it is an overhead traveling type container conveying system, there is a limitation in terms of treatment capacity. In this connection, patent documents such as Japanese Patent Laid-open Nos. 1994-016206 and 2000-353735 and WO00/37338 also disclose methods for delivery and reception of containers to and from treatment apparatuses with use of a carrier or a conveyor. However, there is a limitation in terms of treatment capacity because each of the containers conveying systems disclosed therein is constituted by a single conveyance apparatus.

The third problem is that it is difficult to improve the treatment capacity without increasing the footprint of the conveyance means. The fourth problem is that the container stock function is insufficient. If the container stock function can be expanded, it is possible to diminish the storage capacity of the stocker disposed between processes. Further, the fifth problem is that the container sorting function is not provided. Thus, in the conventional container conveying equipment and systems, there still remains room for improvement.

It is an object of the present invention to solve the above-mentioned problems of the conventional container conveying equipment and systems and provide a container conveying system further improved in terms of conveyance capacity, treatment capacity, foot print, container stock function, container sorting function, and space saving.

According to the present invention, such problems can be solved by a container conveying system for conveying containers containing substrates such as wafers and reticles within a clean room, the container conveying system comprising a conveyance apparatus disposed substantially in parallel with plural treatment apparatuses to convey the containers and a transfer apparatus capable of moving freely in an upper ceiling space within the clean room, the plural treatment apparatuses being arranged on at least one side of a passage and respectively provided with interface devices on the side facing the passage, the interface devices being capable of temporarily receiving the containers and moving the substrates from the interiors of the containers to the interiors of the treatment apparatuses and vice versa in a hermetically sealed atmosphere, and the transfer apparatus delivering and receiving the containers between the conveyance apparatus and the treatment apparatuses or between the treatment apparatuses.

According to this container conveying system, the system is provided with the conveyance apparatus and the transfer apparatus, the conveyance apparatus conveying containers to a predetermined position along the treatment apparatuses, and the transfer apparatus moving freely and three-dimensionally in the upper ceiling space within the clean room which covers the area where the conveying apparatus and the treatment apparatuses are disposed and transferring the containers freely within the operation area of the transfer apparatus, whereby the delivery and reception of the containers can be done between the conveyance apparatus and the treatment apparatuses or between the treatment apparatuses.

Thus, this container conveying system is provided with the conveyance apparatus taking charge of the conveyance of containers along the plural treatment apparatuses and the transfer apparatus moving freely and three-dimensionally in the upper ceiling space within the clean room and taking charge of the delivery and reception of the containers. Since the conveyance and transfer functions are thus separated from each other, it is possible to attain various effects as will be described below.

First, a part of conveyance so far taken charge of by the transfer apparatus can be taken charge of by the conveyance apparatus. Besides, since containers can be conveyed and transferred freely by cooperation of both conveyance means (the conveyance apparatus and the transfer apparatus), the container conveying capacity can be greatly improved as a whole.

Moreover, the conveyance of containers can be done by the conveyance apparatus even during a transfer operation of the transfer apparatus and thus the container conveyance time and the container transfer time can be allowed to overlap each other, whereby the container treatment capacity can be greatly improved.

Further, since plural containers can be placed on the conveyance apparatus and plural containers present at plural (U) places on the conveyance apparatus can be delivered to plural (U) treatment apparatuses, the degree of freedom of the container conveyance to plural treatment apparatuses can be improved from a 1:U relation to a U:U relation.

Since the conveyance apparatus and the transfer apparatus are disposed as one above the other and the conveyance and transfer of the containers are performed by cooperation of both apparatuses, the container treatment capacity can be improved without increasing the foot print of the container conveying system. Further, it is possible to utilize the interior space of the clean room effectively and thereby decrease the equipment cost and the maintenance cost of the clean room.

Further, since the plural containers can be placed and stocked on the conveyance apparatus, the stock function and the stand-by function of the container conveying system are expanded and the storage capacity of an intermediate stocker disposed between the processes can be diminished.

Further, since the plural containers can be placed on the conveyance apparatus and the transfer apparatus can hold any of those containers and deliver them to a predetermined treatment apparatus, the plural containers lying on the conveyance apparatus can be made objects of delivery and hence it is possible to let the conveyance apparatus have a sorting function.

In a preferred mode, the conveyance apparatus has plural conveyance paths and conveyance apparatus units capable of traveling respectively and independently along the conveyance paths. Consequently, the conveyance capacity of the container conveying system can be increased easily. Moreover, by providing the conveyance apparatus units with respective independent drive mechanisms, it is possible to move, stop, or reverse each conveyance apparatus unit independently. Further, it becomes possible to lengthen or change each conveyance path easily, as necessary. Thus, each conveyance apparatus unit can be unitized as an independent apparatus. Therefore, functional properties of the conveyance apparatus can be greatly improved.

In another preferred mode, the plural conveyance paths are arranged as one above the other. As a result, it is possible to utilize the interior space of the clean room effectively and install the plural conveyance apparatus units therein, whereby the equipment cost and the maintenance cost of the clean room can be further reduced.

In a further preferred mode, the plural conveyance paths are arranged on the right and left sides. As a result, loading and unloading of the containers onto the conveyance apparatus become easier and hence it becomes possible to effect stocking and sorting of the containers more easily. Besides, the transfer distance of the transfer apparatus becomes shorter and the transfer time is shortened, whereby the container treatment capacity can be further improved.

In a still further preferred mode, the conveyance apparatus units are each constituted by a conveyor. Thus, the conveyance apparatus can be constituted extremely easily by using a conventional means.

In a still further preferred mode, the transfer apparatus comprises at least two transfer apparatus units. As a result, the container conveying capacity and the treatment capacity can be improved to a far greater extent without increasing the footprint of the container conveying system.

According to the present invention, the foregoing problems can also be solved by a container conveying system for conveying containers containing substrates such as wafers and reticles within a clean room, the container conveying system comprising a conveyance apparatus disposed substantially in parallel with plural treatment apparatuses in an upper ceiling space within the clean room to convey the containers and a transfer apparatus capable of moving freely in a vertical plane extending along the conveyance apparatus in the upper ceiling space within the clean room, the plural treatment apparatuses being arranged on at least one side of a passage and respectively provided with interface devices on the side facing the passage, the interface devices being capable of temporarily receiving the containers and moving the substrates from the interiors of the containers to the interiors of the treatment apparatuses and vice versa in a hermetically sealed atmosphere, and the transfer apparatus delivering and receiving the containers between the conveyance apparatus and the treatment apparatuses or between the treatment apparatuses.

According to this container conveying system, the system is provided with the conveyance apparatus and the transfer apparatus in the upper ceiling space within the clean room, the conveyance apparatus conveying containers to a predetermined position along the plural treatment apparatuses, and the transfer apparatus moving in a vertical plane extending along the conveyance apparatus within the upper ceiling space within the clean room which covers the area where the treatment apparatuses are disposed to transfer freely the containers lying in the operation area thereof, whereby the delivery and reception of containers can be done between the conveyance apparatus and the plural treatment apparatuses or between the treatment apparatuses. Thus, the container conveying system is provided with the conveyance apparatus moving along the treatment apparatuses through the upper ceiling space within the clean room and taking charge of the conveyance of containers and the transfer apparatus moving along the conveyance apparatus through the upper ceiling space within the clean room and taking charge of the delivery and receipt of containers. Since the container conveying function and the container transfer function are separated from each other, various effects can be obtained as will be described below.

First, a part of conveyance so far taken charge of by the transfer apparatus can be taken charge of by the conveyance apparatus, and by cooperation of both conveyance means (the conveyance apparatus and the transfer apparatus), containers can be conveyed and transferred freely to the plural treatment apparatuses arranged in the container conveying and transferring directions of both conveyance means. Consequently, the container conveying capacity can be greatly improved as a whole.

Moreover, the conveyance of containers can be done by the conveyance apparatus even during a transfer operation of the transfer apparatus and thus the container conveyance time and the container transfer time can be allowed to overlap each other, whereby the container treatment capacity can be greatly improved.

Further, since plural containers can be placed on the conveyance apparatus and plural containers present at plural (U) places on the conveyance apparatus can be delivered to plural (U) treatment apparatuses, the degree of freedom of the container conveyance to plural treatment apparatuses can be improved from a 1:U relation to a U:U relation.

Since the conveyance apparatus and the transfer apparatus are arranged adjacent to and in parallel with each other in the upper ceiling space within the clean room and the conveyance and transfer of containers are performed by cooperation of both conveyance apparatus and transfer apparatus, the container treatment capacity can be improved without increasing the foot print of the container conveying system. Moreover, the interior space of the clean room can be utilized effectively while utilizing a space below the conveyance apparatus as a worker passage, whereby the space of the clean room can be largely saved and it is possible to reduce the equipment cost and the maintenance cost of the clean room.

Further, since the plural containers can be placed and stocked on the conveyance apparatus, the stock function and the stand-by function of the container conveying system are expanded and the storage capacity of an intermediate stocker disposed between the processes can be diminished.

Further, since the plural containers can be placed on the conveyance apparatus and the transfer apparatus can hold any of those containers and deliver them to a predetermined treatment apparatus, the plural containers lying on the conveyance apparatus can be made objects of delivery and hence it is possible to let the conveyance apparatus have a sorting function.

In a preferred mode, plural branch conveyance paths are formed at appropriate intervals in the conveyance direction of the conveyance apparatus and are able to receive the containers having been conveyed by the conveyance apparatus and allow the containers to stand by; and the transfer apparatus can hold the stand-by containers on the branch conveyance paths and deliver the containers to any of the treatment apparatuses. Thus, the containers which have been received by the branch conveyance paths can stand by in a standstill state on the branch conveyance paths until the transfer apparatus carries the containers to a predetermined treatment apparatus. That is, it is not necessary for the containers to stand by on the conveyance apparatus for the transfer onto the transfer apparatus, and thus the containers do not obstruct other containers forwarding by being conveyed by the conveyance apparatus. As a result, the container treatment capacity can be further improved as a whole.

In another preferred mode, plural treatment apparatuses are arranged on both sides of a passage, the conveyance apparatus is provided with two conveyance apparatus units traveling respectively along two conveyance paths which are a going path and a returning path; and the transfer apparatuses are provided on the right and left sides respectively of the conveyance apparatus. According to this arrangement, in the intra-clean room production line wherein the plural treatment apparatuses are arranged on both sides of the passage, both conveyance means (the conveyance apparatus and the transfer apparatus) can be arranged concentratively and symmetrically right and left in the upper ceiling space while ensuring the worker passage centrally; and thus the conveyance and transfer of containers to the plural treatment apparatuses on both sides of the passage can be taken charge of by both conveyance means (the conveyance apparatus and the transfer apparatus) disposed on the right and left sides, whereby it is possible to utilize the space effectively and further improve the container treatment capacity. Besides, it becomes possible to place a larger number of containers on the conveyance apparatus and the stock function, stand-by function and sorting function of the container conveying system can be further expanded.

In a further preferred mode, the two conveyance paths are arranged transversely in parallel. As a result, the structure of the conveyance apparatus including a transfer mechanism or the like for connecting the two conveyance apparatus units which travel along the two going and returning conveyance paths can be simplified.

In a still further preferred mode, the two conveyance paths are arranged vertically in parallel. According to this arrangement, since the two conveyance apparatus units which travel along the two going and returning conveyance paths respectively are disposed as one above the other and are thus assembled three-dimensionally, the space between the treatment apparatuses (treatment apparatus groups) arranged on both sides of the paths becomes narrower. Although the worker passage becomes a little narrower as saving the space to a minimum requirement, it is possible to further decrease the equipment cost and the maintenance cost of the clean room.

### BRIEF DESCRIPTION OF THE DRAWINGS

FIG. 1 is a layout diagram of a treatment area in an intra-clean room production line to which a container conveying system according to an embodiment (first embodiment) of the present invention is applied;

FIG. 2 is a perspective view showing a basic construction of a treatment area in the intra-clean room production line to which the container conveying system is applied;

FIG. 3 is a plan view thereof

FIG. 4 is a side view thereof,

FIG. 5 is a side view showing a basic construction of a treatment area in an intra-clean room production line to which a container conveying system according to another embodiment (second embodiment) of the present invention is applied, corresponding to FIG. 4;

FIG. 6 is a plan view showing a basic construction of a treatment area in an intra-clean room production line to which a container conveying system according to a further embodiment (third embodiment) of the present invention is applied;

FIG. 7 is a left side view thereof,

FIG. 8 is an inner side view thereof,

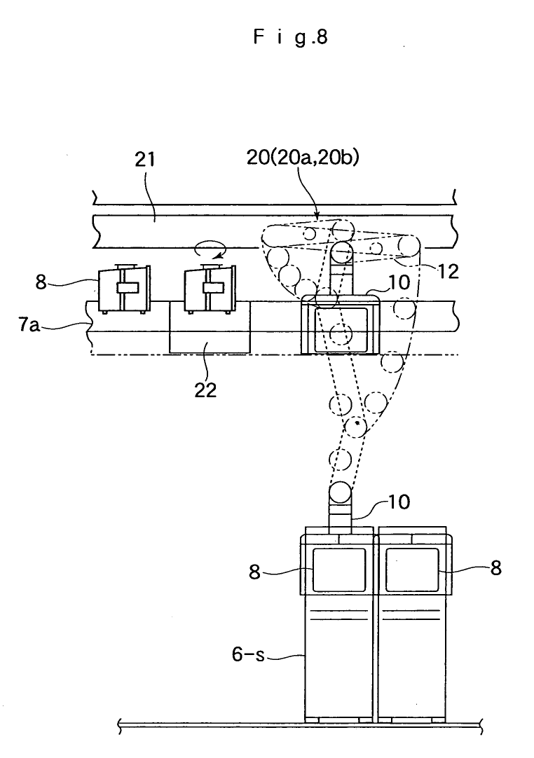

FIG. 9 is a plan view showing a basic construction of a treatment area in an intra-clean room production line to which a container conveying system according to a still further embodiment of the present invention (fourth embodiment) is applied;

FIG. 10 is a left side view thereof and

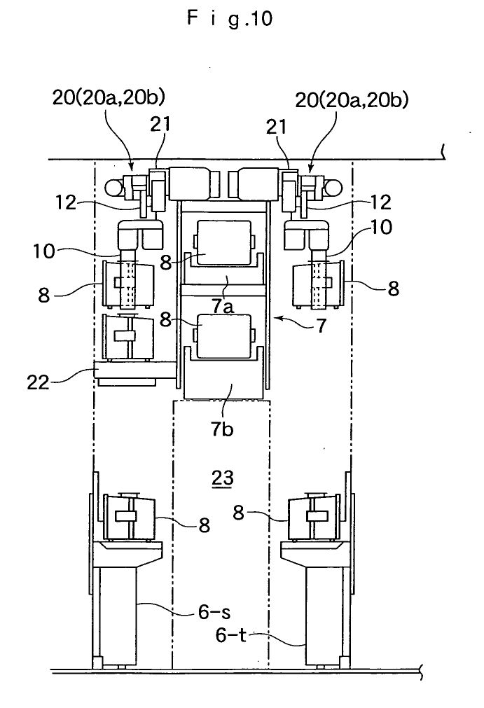

FIG. 11 is an inner side view thereof.

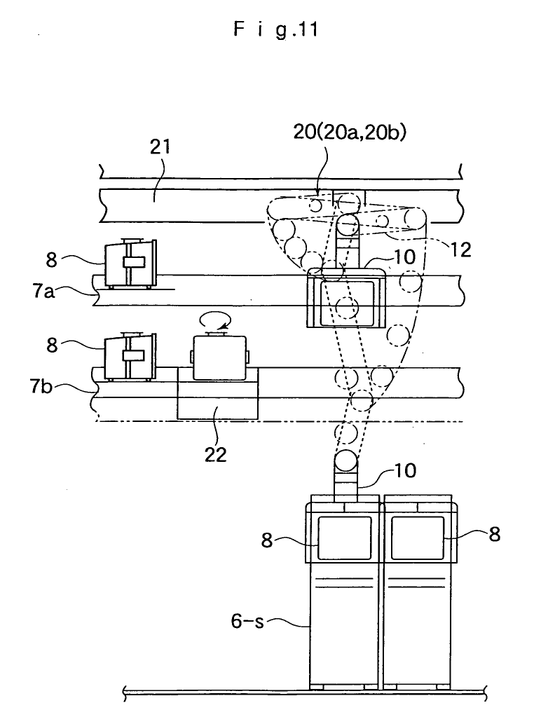

### BEST MODE FOR CARRYING OUT THE INVENTION

A container conveying system according to a first embodiment of the present invention is used for the conveyance of containers such as FOUP or SMIF pods containing various substrates such as semiconductor substrates including wafers and reticles, or glass substrates, between plural treatment apparatuses installed in an intra-clean room production line particularly in a manufacturing factory for the manufacture of semiconductor devices or liquid crystal devices.

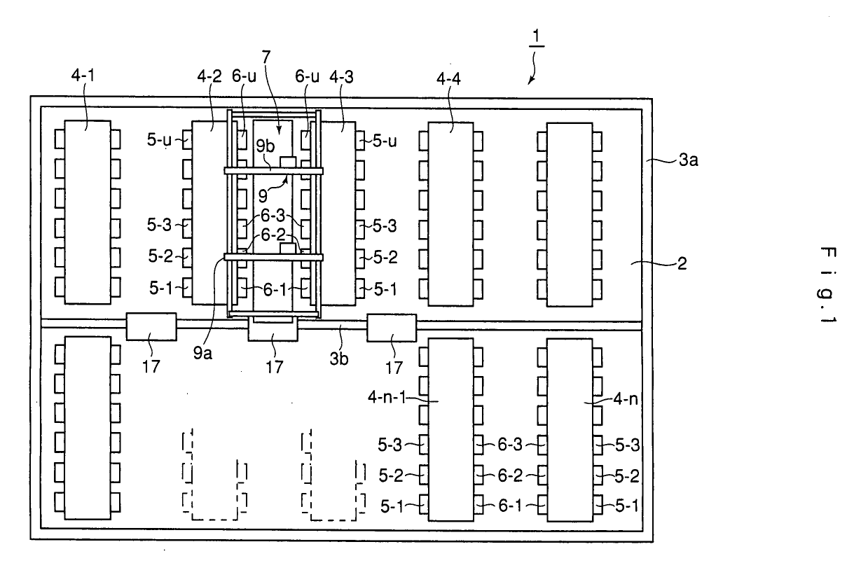

A layout of a treatment area in the intra-clean room production line in the manufacturing factory as mentioned above is shown in FIG. 1.

In an intra-clean room production line 1, as shown in FIG. 1, plural treatment apparatus groups 4-1, 4-2, 4-3, . . . 4-n are arranged side by side in the direction along a central inter-process conveyance path 3b within both areas adjacent to each other on both sides of the linear inter-process conveyance path 3b, the both areas being partitioned by a rectangular inter-conveyance path 3a extending throughout the whole periphery of a floor surface 2 and the inter-process conveyance path 3b which divides the floor surface 2 into two.

Each treatment apparatus group 4-m (m≦n) comprises plural treatment apparatuses 5-1, 5-2, 5-3, . . . which are arranged in the direction orthogonal to the inter-process conveyance path 3b. The treatment apparatuses 5-1, 5-2, 5-3, . . . are apparatuses for treating intra-container works (substrates) in a successive manner. The treatment apparatuses perform different treatments respectively, but plural treatment apparatuses may be allowed to perform the same treatment, taking a balance of tact time in work treatment into account.

As examples of such treatment apparatuses there is a treatment apparatus for performing resist application, exposure, development, ion implantation, annealing, and sputtering, for semiconductor wafers. With treatments for semiconductor wafers in mind, the following description is provided.

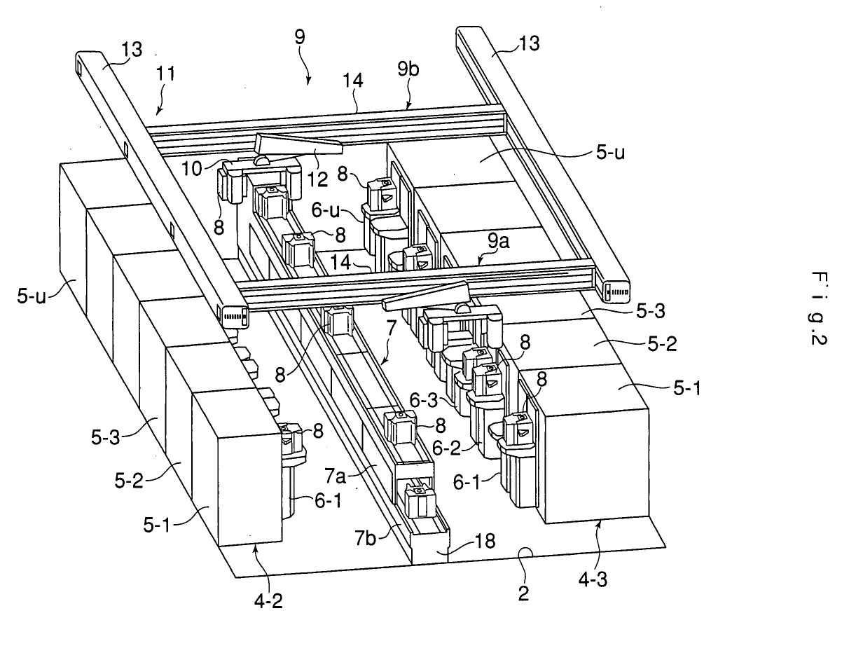

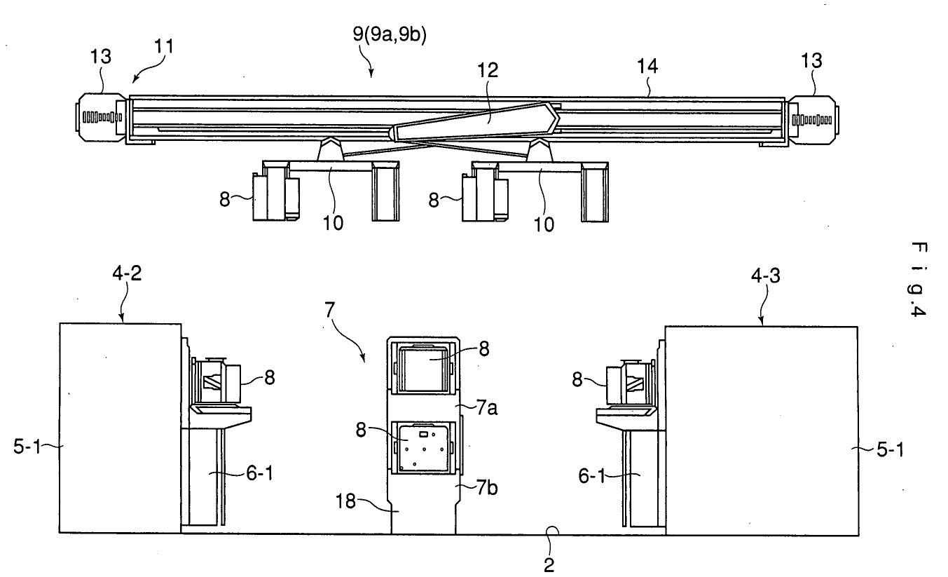

Between a treatment apparatus group 4-m and a treatment apparatus group 4-m+1, there usually is a passage for maintenance and a conveyance apparatus 7 is installed in the said passage substantially in parallel with the plural treatment apparatuses 5-1, 5-2, 5-3, . . . which respectively belong to the treatment apparatus groups, as shown in detail in FIGS. 2 to 4 which show a treatment area comprising the treatment apparatus groups 4-2 and 4-3 on a larger scale.

Next, a structure of the conveyance apparatus 7 will be described in detail below.

The conveyance apparatus 7 has two conveyance paths arranged as one above the other on top of a base 18 self-standing up from the floor surface 2 and is provided with two conveyance apparatus units 7a and 7b traveling along those conveyance paths respectively.

Plural substrate containers 8 to be described later can be placed on conveyance portions of the two conveyance apparatus units 7a and 7b. Thus, the conveyance apparatus 7 can store plural containers 8 temporarily, having a stock function. Conveyance sequence of the plural containers 8 thus stored temporarily can be changed as desired by means of a transfer apparatus (a three-dimensional moving mechanism) 9 to be described later, and thus the conveyance apparatus 7 also has a sorting function for the containers 8. Loading and unloading of the containers 8 to and from the lower conveyance apparatus unit 7b are performed at one end portion of the upper conveyance apparatus unit 7a which has been made shorter in length by being cut off (the right lower portion in FIG. 2).

By the stock function of the containers 8 is meant a function of storing the containers 8 until conveyance to the next treatment process, the containers 8 containing wafers after subjected to a certain treatment process. For fulfilling such a function there usually is provided an intermediate stocker between processes. An intermediate (inter-process) stocker 17 to be described later corresponds to such an intermediate stocker. By allowing not only the intermediate stocker but also the conveyance apparatus 7 to have such a function, it becomes possible to let the containers 8 stand by also on the conveyance apparatus 7 and the storage capacity of the intermediate stocker is consequently diminished, whereby the operation efficiency of the intermediate stocker can be improved.

The sorting function for the containers 8 indicates the following function. In a series of wafer treating processes, the container 8 which contains wafers after subjected to a certain treatment is to stand by within the intermediate stocker until being conveyed to the next treatment process. In this case, if the next treatment process is performed in the same order as in the preceding process, there occurs no problem. However, in a complicated treatment process there may be a need for changing the container conveyance sequence or a treatment process. In such a case, it is necessary to re-arrange the sequence of the containers 8. The function which can satisfy such a requirement is the sorting function. By allowing not only the intermediate stocker but also the conveyance apparatus 7 to have such a function as mentioned above, it becomes possible to re-arrange the sequence of the containers 8 during conveyance, to shorten the conveyance tact time, and to improve the conveyance efficiency of the containers 8.

The upper conveyance apparatus unit 7a as a constituent of the conveyance apparatus 7 is designed so that the height of a conveyance portion of the conveyance apparatus unit does not exceed approximately 900 mm from the floor surface 2. As the conveyance portion, there may be used various types of conveyers, including a roller conveyor using rotating rollers as surfaces in contact with the containers 8, a belt conveyor using a belt, a pallet conveyor using a pallet, and a slat conveyor provided with a positioning jig.

The two conveyance apparatus units 7a and 7b may be respectively provided with individual drive mechanisms, whereby the conveyance apparatus units can be moved, stopped, or reversed, each independently as necessary. Moreover, the conveyance paths can be easily lengthened or changed as necessary. Thus, each of the conveyance apparatus units 7a and 7b can be unitized as an independent unit, whereby the functional properties of the conveyance apparatus 7 can be improved remarkably.

Further, the conveyance apparatus units 7a and 7b may be constructed so as to perform complicated operations by being added a positioning device for the containers 8, a rotating device for changing the direction of the containers 8, a shift device for changing the conveyance direction to the direction perpendicular thereto, and an elevator for changing the vertical conveyance height. In this case, for adding these devices also to the lower conveyance apparatus unit 7b, a framework structure is preferably made between the upper conveyance apparatus unit 7a and the lower conveyance apparatus unit 7b, whereby the containers 8 can be loaded and unloaded also sideways of the lower conveyance apparatus unit 7b.

It is not always necessary that the two conveyance apparatus units 7a and 7b be provided. It suffices if at least one is provided.

The treatment apparatuses 5-1, 5-2, 5-3, . . . are respectively provided with the interface devices 6-1, 6-2, 6-3, . . . on the side facing the passage, i.e., on the side facing the conveyance apparatus 7. The interface devices 6-1, 6-2, 6-3, . . . constitute buffer spaces for shutting off the interiors of the treatment apparatuses 5-1, 5-2, 5-3, . . . from the clean room. With the interface devices 6-1, 6-2, 6-3, . . . , which are normally closed, when containers 8 are temporarily received onto tables disposed on the side facing the passage, substrates contained in the containers 8 can be moved from the interiors of the containers 8 to the interiors of the treatment apparatuses 5-1, 5-2, 5-3, . . . or vice versa in a hermetically sealed atmosphere.

Above the conveyance apparatus 7, in the upper ceiling space in the area including the treatment apparatus groups 4-2 and 4-3 within the clean room, a three-dimensional moving mechanism 9 which can freely move in the said ceiling space is provided. The three-dimensional moving mechanism 9 is a transfer apparatus for the containers 8 which transfer device can freely move in the ceiling space while holding containers 8 and deliver the containers between arbitrary two points.

Next, the structure of the transfer apparatus (three-dimensional moving mechanism) 9 will be described below in detail.

The transfer apparatus 9 comprises two transfer apparatus units 9a and 9b. The transfer apparatus 9 may be provided with three or more transfer apparatus units, but the control becomes complicated and therefore the provision of two transfer apparatus units is preferred. Since the transfer apparatus units 9a and 9b are of the same structure, a description will be given below of only the transfer apparatus unit 9b. The transfer apparatus 9 is sometimes called a gantry robot.

As shown in FIGS. 2 to 4, the transfer apparatus unit 9b includes a container holding means 10 for holding the containers 8, a horizontal moving means 11 for moving the container holding means 10 horizontally in the upper ceiling space within the clean room, and a lift means 12 provided in the horizontal moving means 11 to raise, lower, and rotate the container holding means 10 while suspending the container holding means.

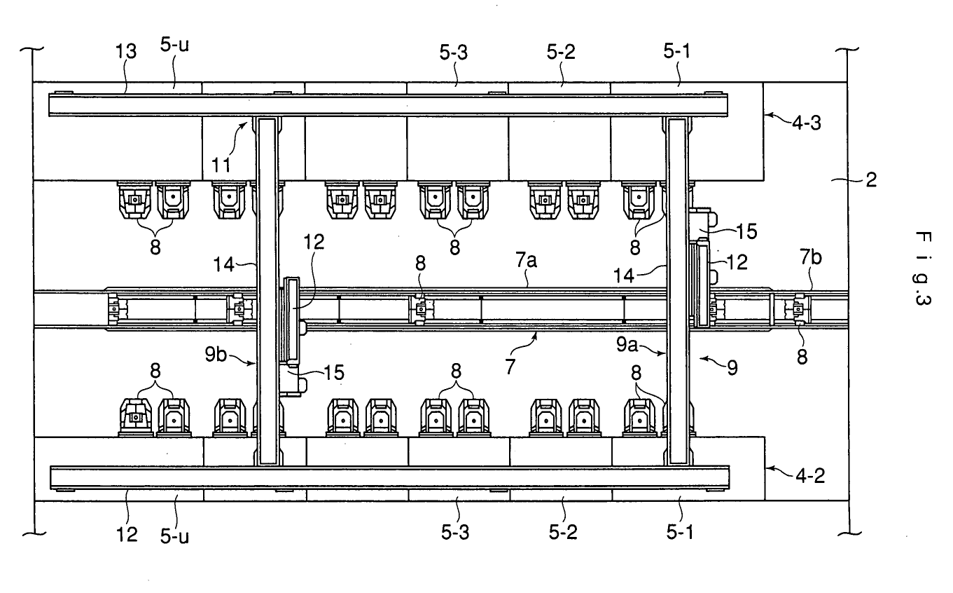

The horizontal moving means 11 comprises a pair of horizontal fixed guide rails 13 disposed in parallel in the upper ceiling space within the clean room, travel guide rails 14 disposed bridgewise between the pair of horizontal fixed guide rails 13, and traveling members 15 (see FIG. 3) disposed so as to be capable of traveling along the travel guide rails 14. The horizontal moving means 11 permits an arbitrary movement of the traveling members 15 in a horizontal XY plane sandwiched between the pair of fixed guide rails 13 in the upper ceiling space within the clean room. As a result, the lift means 12 and the container holding means 10 are moved linearly from a certain position to another position on the opposite side with respect to the central passage so that the container holding means 10 lies just above the container tables of the interface devices 6-1, 6-2, 6-3, . . . The pair of horizontal fixed guide rails 13 are disposed above the treatment apparatus groups 4-2 and 4-3 and are supported by plural support posts (not shown).

In a travel drive mechanism for each traveling member 15, although the details thereof are not shown, a motor integrated with the traveling member is accommodated within the associated travel guide rail 14 and a roller fixed to a rotary shaft of the motor rolls along an inner wall surface of the travel guide rail 14, whereby the traveling member 15 travels along the travel guide rail 14. A base end portion (upper end portion) of the lift means 12 is fixedly connected to the traveling member 15 and is to travel together with the traveling member 15.

The lift means 12 is constituted by an articulated arm. The articulated arm extends and retracts as plural arms pivot around joints. The container holding means 10 is attached rotatably to a front end of a final-stage arm. The container holding means 10 has two holding portions so that two containers can be held at the same time. Further, the container holding means 10 can be used in such a manner that, while one holding portion loads a container, the other holding portion can take up another container.

The container conveying system of this first embodiment is a total conveyance system for the containers 8 made up of the above-described constituent apparatuses and devices, i.e., the conveyance apparatus 7, the transfer apparatus 9, and the interface devices 6-1, 6-2, 6-3, . . . respectively provided in the treatment apparatuses 5-1, 5-2, 5-3, . . . , which are assembled in a predetermined linkage relation. These constituent apparatuses and devices are associated with the conveyance of the containers 8 in the respective modes described above.

In the intra-clean room production line 1, plural intermediate (inter-process) stockers 17 are disposed on the central linear inter-process conveyance path 3b. Each of the intermediate stockers 17 is disposed on the inter-process conveyance path 3b between adjacent treatment apparatus groups, e.g., between one set of the treatment apparatus groups 4-2 and 4-3, in which the transfer apparatus 9 is provided. A container 8 containing works having been treated in a treatment area consisting of the one set of treatment apparatus groups (usually all the treatments performed in this treatment area are regarded as one unit and designated “one treatment process”) is conveyed to the intermediate stocker 17 by means of the transfer apparatus 9 or a working robot (not shown) and is stocked in the intermediate stocker. Then, when the next treatment area is empty, the container 8 is delivered to an inter-process conveyance apparatus (not shown) traveling along the inter-process conveyance paths 3a and 3b and is thereby conveyed to the empty, new treatment area.

As noted above, the conveyance apparatus 7 is installed in the treatment area including the set of treatment apparatus groups, in which the transfer apparatus 9 is provided. Since the conveyance apparatus 7 has a stock function and can be utilized as a stand-by place, the storage capacity of each intermediate (inter-process) stocker 17 can be designed so much smaller. Furthermore, it is possible to level the load of the inter-process conveyance apparatus and ensure a stable conveyance capacity. For example, ten containers 8 can be allowed to stand by for one conveyance apparatus 7. Assuming that there are a total of forty conveyance apparatuses 7, a maximum of four hundred containers can be stocked on the conveyance apparatuses 7 side and the storage capacity of the intermediate (inter-process) stockers 17 can be so much reduced.

Next, the operation of the container conveying system of this first embodiment constructed as above will be described below in detail with reference to FIGS. 2 and 3.

A description will now be given about the case where a container 8 (the rightmost container 8 on the treatment apparatus group 4-2 side in FIG. 3) placed on the container table of the interface device 6-1 of the treatment apparatus 5-1 belonging to the treatment apparatus group 4-2 is to be transferred onto the container table (the table on which the leftmost container 8 on the treatment apparatus group 4-3 side is placed in FIG. 3) of the interface device 6-u of the treatment apparatus 5-u belonging to the treatment apparatus group 4-3.

In this case, first the travel guide rail 14 of the transfer apparatus unit 9a moves rightward in FIG. 3 up to just above the container 8 to-be-transferred on the treatment apparatus group 4-2 side, then the traveling member 15 thereof moves downward in FIG. 3 until the holding means 10 arrives at the position just above the container 8, then the lift means 12 extends (descends) and one holding portion of the holding means 10 attached to the lowest end of the lift means holds the container 8.

Subsequently, the lift means retracts (ascends) and the traveling member 15 moves until the holding means 10 which holds the container 8 arrives at the position just above the conveyance apparatus unit 7a, and after re-extension of the lift means 12, the holding means 10 loads the container 8 which the holding means holds onto the conveyance apparatus unit 7a.

Next, the conveyance apparatus unit 7a travels leftward in FIG. 3 and carries the thus-loaded container 8 up to the position in front of the container table of the interface device 6-u of the treatment apparatus 5-u belonging to the treatment apparatus group 4-3. In the meantime, also in the transfer apparatus unit 9b, the travel guide rail 14 and the traveling member 15 move leftward and upward respectively in FIG. 3 so that the holding means 10 lies just above a predetermined arrival position of the container 8 to-be-transferred which lies on the conveyance apparatus unit 7a.

Then, the lift means 12 of the transfer apparatus unit 9b extends and the empty holding portion of the holding means 10 attached to the lowest end of the lift means 12 holds the container 8 lying on the conveyance apparatus unit 7a. Next, the traveling member 15 of the transfer apparatus unit 9b moves until the holding means 10 which holds the container 8 arrives at the position just above the container table of the interface device 6-u, and after re-extension of the lift means 12, the holding means 10 loads the container 8 which the holding means holds onto the container table. In this way a required container transfer work is completed.

Thus, when the container 8 placed on the container table of the interface device 6-1 of the treatment apparatus 5-1 belonging to the treatment apparatus group 4-2 is to be transferred onto the container table of the interface device 6-u of the treatment apparatus 5-u belonging to the treatment apparatus group 4-3, the container transfer work is conducted by cooperation of the transfer apparatus unit 9a, the conveyance apparatus 7a, and the transfer apparatus unit 9b. Consequently, the transfer distance of the transfer apparatus units 9a and 9b is shortened; the foot print of the container conveying system becomes smaller, making the saving of space possible; and the container conveying capacity and the treatment capacity can be greatly improved.

Particularly, the transfer range for each of the transfer apparatus units 9a and 9b is limited, even at most, to an area which is defined by traveling of the associated travel guide rail 14 over a half length of the fixed guide rail 13, and is reduced by half in comparison with a conventional container conveying system not provided with the conveyance apparatus 7. Particularly in the case where the transfer distance is long in the above case, the improvement in the conveyance capacity and the treatment capacity for the containers 8 are remarkable. In such a case, if the transfer of the containers 8 throughout the overall length of the transfer distance is relied on only one transfer apparatus unit, there occurs an excessive load in structural strength and it takes much time.

The above operation of the container conveying system of this first embodiment is also basically true for the case where a container 8 placed on an container table of the interface device 6-t of an arbitrary treatment apparatus 5-t (t<u) belonging to an arbitrary treatment apparatus group 4-m is transferred onto the container table of an interface device 6-s of an arbitrary treatment apparatus 5-s (1<s≦u) belonging to the adjacent treatment apparatus group 4-m+1 which confronts the treatment apparatus group 4-m with respect to the conveyance apparatus 7. Therefore, a detailed description about such a case will here be omitted.

In the above first embodiment, the treatment apparatuses 5-1, 5-2, 5-3, . . . are arranged on both sides of the passage in which the conveyance apparatus 7 is installed and the interface devices 6-1, 6-2, 6-3, . . . are provided on the side facing the passage (see, for example, the treatment apparatuses 5-1, 5-2, 5-3, . . . belonging to the treatment apparatus groups 4-2 and 4-3). However, no limitation is imposed on the arrangement of the treatment apparatuses. The treatment apparatuses 5-1, 5-2, 5-3, . . . may be arranged on only one side of the passage and the interface devices 6-1, 6-2, 6-3, . . . may be provided on the side facing the passage. In this case, the transfer apparatus 9 may be provided so as to straddle the treatment apparatuses 5-1, 5-2, 5-3, . . . arranged on only one side of the passage and the conveyance apparatus 7 installed in the passage.

Since the container conveying system of this first embodiment is constructed as above, the following effects can be obtained.

The container conveying system is provided with the conveyance apparatus 7 and the transfer apparatus 9. The conveyance apparatus 7 conveys containers up to a predetermined position along the treatment apparatuses 5-1, 5-2, 5-3, . . . , while the transfer apparatus 9 freely and three-dimensionally moves in the upper ceiling space within the clean room which covers the area where the conveyance apparatus 7 and the treatment apparatuses 5-1, 5-2, 5-3, . . . are arranged, then freely transfers the containers 8 present within an operation area for the transfer apparatus. Thus, the delivery and receipt of the containers 8 can be done between the conveyance apparatus 7 and the treatment apparatuses 5-1, 5-2, 5-3, . . . or between the treatment apparatuses 5-1, 5-2, 5-3, . . .

Thus, the container conveying system is provided with the conveyance apparatus 7 taking charge of conveyance of the containers 8 along the treatment apparatuses 5-1, 5-2, 5-3, . . . and the transfer apparatus 9 freely and three-dimensionally moving in the upper ceiling space within the clean room and taking charge of the delivery and receipt of the containers 8, and the respective functions are separated from each other. Accordingly, there can be obtained such various effects as will be described below.

First, a part of the conveyance so far taken charge of by the transfer apparatus can be taken charge of by the conveyance apparatus 7 and the containers 8 can be conveyed and transferred freely by cooperation of both conveyance means (the conveyance apparatus 7 and the transfer apparatus 9), so that the conveyance capacity for the containers 8 can be greatly improved as a whole.

Besides, even when the transfer apparatus 9 is performing its transfer operation, the containers 8 can be conveyed up to a predetermined position by the conveyance apparatus 7 and the container transfer time and the container conveyance time can be allowed to overlap each other, so that the treatment capacity for the containers 8 can be greatly improved.

Moreover, plural containers 8 can be placed on the conveyance apparatus 7 and plural containers 8 lying at plural (U) places on the conveyance apparatus 7 can be delivered to plural (U) treatment apparatuses 5-1, 5-2, 5-3, . . . , so that the degree of freedom of the container conveyance to the plural treatment apparatuses 5-1, 5-2, 5-3, . . . can be improved from a 1:U relation to a U:U relation.

Further, since the conveyance apparatus 7 and the transfer apparatus 9 are arranged as one above the other and the conveyance and transfer of the containers 8 are performed by the cooperation of both apparatuses, the container treatment capacity can be improved without increasing the foot print of the conveyance means (the container conveying system). Further, the equipment cost and the maintenance cost of the clean room can be reduced by effectively utilizing the interior space of the clean room.

Further, since plural containers 8 can be placed and stocked on the conveyance apparatus 7, the stock function and the stand-by function of the container conveying system are expanded and it is possible to diminish the storage capacity of the intermediate stockers 17 which are disposed between processes.

Since the plural containers 8 can be placed on the conveyance apparatus 7 and the transfer apparatus 9 can hold any one of the containers 8 and deliver the container to a predetermined treatment apparatus 5-r (r≦u), the plural containers 8 lying on the conveyance apparatus 7 can be made objects of delivery and thus it is possible to let the conveyance apparatus 7 have a sorting function.

Since the conveyance apparatus 7 is provided with plural conveyance paths and conveyance apparatus units 7a and 7b which can respectively and independently travel along each conveyance path, the conveyance capacity of the container conveying system can be increased easily. By providing the conveyance apparatus units 7a and 7b with independent drive mechanisms respectively, each conveyance apparatus unit can independently be moved, stopped, or reversed as necessary. It is also possible to easily lengthen or change the conveyance paths as necessary. Thus, the conveyance apparatus units 7a and 7b can be unitized as independent units respectively and hence the functional properties of the conveyance apparatus 7 can be improved remarkably.

Since the conveyance paths for travel of the conveyance apparatus units 7a and 7b are arranged as one above the other, the plural conveyance apparatus units 7a and 7b can be installed by utilizing the interior space of the clean room effectively and thus the equipment cost and the maintenance cost of the clean room can be further reduced.

In the case where each of the conveyance apparatus units 7a and 7b is constituted by a conveyor, the conveyance apparatus 7 can be constituted extremely easily by using a conventional means.

Further, since the transfer apparatus 9 is constituted by at least two transfer apparatus units 9a and 9b, the conveyance capacity and the treatment capacity for the containers 8 can be improved to a greater extent without increasing the foot print of the container conveying system.

Thus, various effects can be obtained by the container conveying system of this first embodiment.

Next, a container conveying system according to another embodiment (second embodiment) of the present invention will be described below.

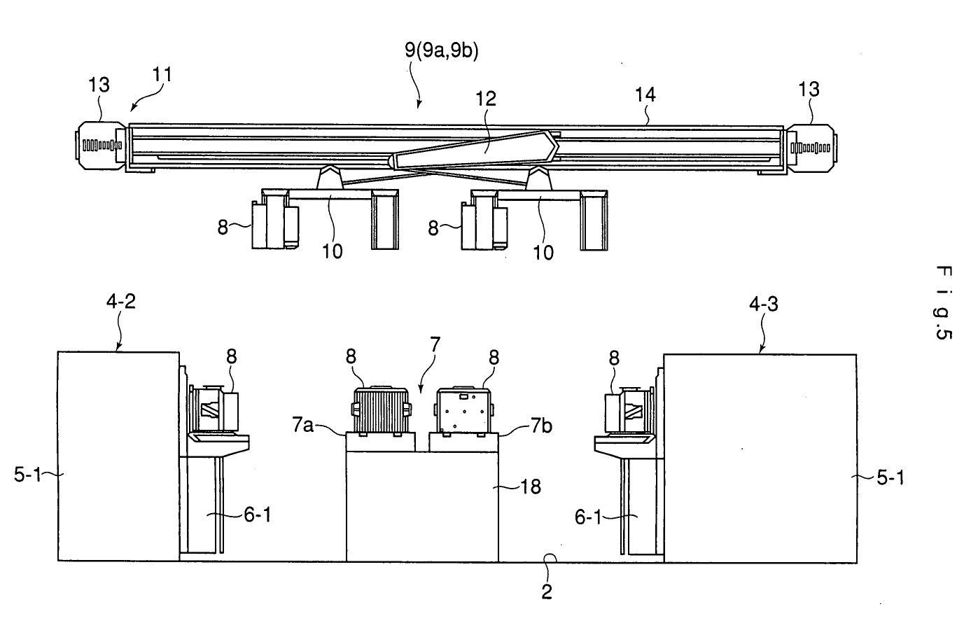

In the container conveying system of this second embodiment, as shown in FIG. 5, a conveyance apparatus 7 has two conveyance paths disposed on the right and left sides on top of a base 18 self-standing up on a floor surface 2, and a left conveyance apparatus unit 7a and a right conveyance apparatus unit 7b traveling along the conveyance paths respectively are provided.

Only in this point the second embodiment is different from the first embodiment, with other constructional points being the same. Therefore, a detailed description will here be omitted.

In the container conveying system of this second embodiment constructed as above, the whole conveyance apparatus unit 7b which in the first embodiment underlies the conveyance apparatus unit 7a appears to the exterior. Consequently, loading and unloading of containers 8 onto the conveyance apparatus 7 by a transfer apparatus 9 become easier and stocking and sorting of the containers 8 can be done more easily.

The loading and unloading of the containers 8 can be done at any position of the right conveyance apparatus unit 7b and the right conveyance apparatus unit 7b can be disposed at a higher position. As a result, the transfer distance of the transfer apparatus 9 also becomes shorter and hence the transfer time is so much shortened. Accordingly, the container treatment capacity can be further improved.

In the above first and second embodiments, the transfer apparatus 9 is arranged so as to, at most, straddle two treatment apparatus groups (treatment apparatus groups 4-m and 4-m+1, each comprising plural treatment apparatuses 5-1, 5-2, 5-3, . . .) arranged on both sides of a passage and the conveyance apparatus 7 installed in the said passage facing the two treatment apparatus groups. However, no limitation is imposed on the arrangement of the transfer apparatus. The transfer apparatus 9 may be arranged in an expanded manner so as to straddle a larger number of treatment apparatus groups and the conveyance apparatuses 7.

Although in the first and second embodiments, the two treatment apparatus groups (treatment apparatus groups 4-2 and 4-3) arranged on both sides of the passage comprise the same number of treatment apparatuses 5-1, 5-2, 5-3, . . . 5-u, this does not mean that each of plural treatment apparatus groups 4-1, 4-2, 4-3, . . . 4-n always comprises the same number of treatment apparatuses. Even in the case where each of the two treatment apparatus groups arranged on both sides of the passage comprises a different number of treatment apparatuses, the transfer apparatus 9 can operate in almost the same manner as described above.

A container conveying system according to a further embodiment (third embodiment) of the present invention will be described below.

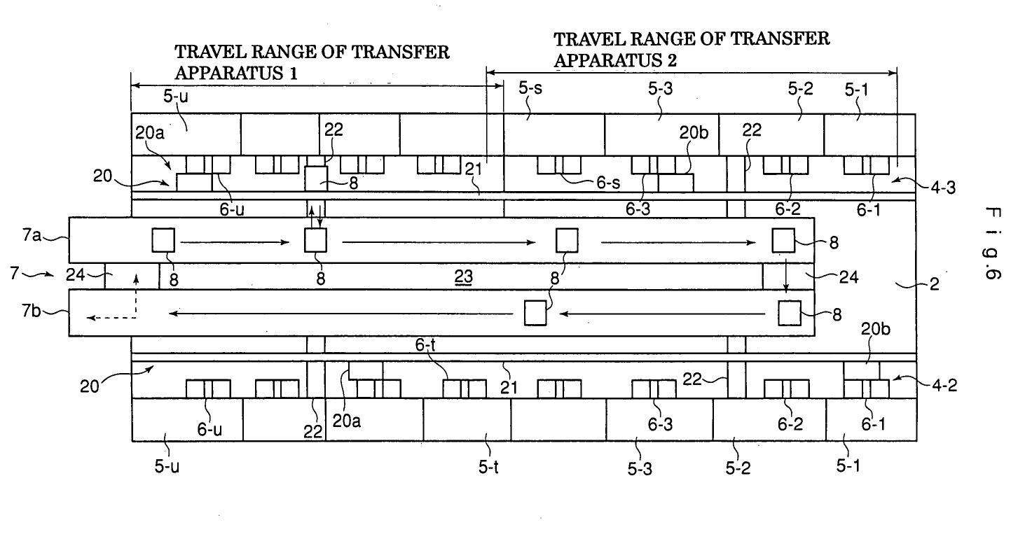

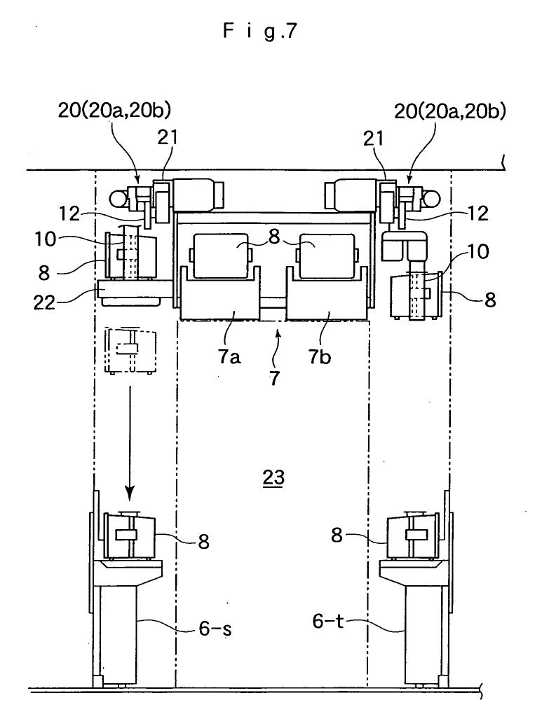

In this third embodiment, in one area of the intra-clean room production line, as shown in FIGS. 6 and 7, treatment apparatus groups 4-2 and 4-3 are respectively arranged on both sides of a central passage 23. Further, in the ceiling space above the passage 23, a conveyance apparatus 7 is provided along the passage 23 and transfer apparatuses 20 are provided on both sides of the conveyance apparatus 7. The two transfer apparatuses 20 can move freely in a vertical plane (a two-dimensional space) running along the conveyance apparatus 7 through the upper ceiling space within the clean room.

Each of the treatment apparatus groups 4-2 and 4-3 comprises plural treatment apparatuses 5-1, 5-2, 5-3, . . . The treatment apparatuses 5-1, 5-2, 5-3, . . . are arranged regularly in one row along the passage 23 and are respectively provided with interface devices 6-1, 6-2, 6-3, . . . on the side facing the passage 23.

The conveyance apparatus 7 has two conveyance paths, which are arranged on the right and left sides in parallel with each other and substantially in parallel with the treatment apparatus groups 4-2 and 4-3 respectively. Further, a left conveyance apparatus unit 7a and a right conveyance apparatus unit 7b traveling along the conveyance paths respectively are provided. The left conveyance apparatus unit 7a serves as a going path, while the right conveyance apparatus unit 7b serves as a returning path, the going and returning paths being connected to each other at their end portions on both sides through shift mechanisms 24.

Containers 8 being conveyed on the conveyance apparatus 7 flow rightwards on the left conveyance apparatus unit 7a like arrows in FIG. 6, then are reversed their flowing direction and shifted onto the right conveyance apparatus unit 7b by the shift mechanism 24 concerned, and flow leftwards on the right conveyance apparatus unit 7b like arrows in FIG. 6. In this way, the containers 8 are allowed to flow in predetermined directions from an inlet to an outlet. A modification may be made such that the flowing direction of each container 8 is reversed and shifted onto the left conveyance apparatus unit 7a by the shift mechanism 24 concerned at a terminal end portion (the left end portion in FIG. 6) of the right conveyance apparatus unit 7b and the container 8 again flows on the left conveyance apparatus unit 7a. Conveyors are used as the conveyance apparatus units 7a and 7b, but no limitation is imposed on the conveyance apparatus units.

Plural branch conveyance paths 22 are provided in each of the left and right conveyance apparatus units 7a and 7b at appropriate intervals in the container conveying direction so as to protrude outwards. Each of the branch conveyance paths 22 can receive one of the containers 8 conveyed by the conveyance apparatus units 7a and 7b and let the container stand by. As to the containers 8 flowing on the conveyance apparatus 7, computers all manage which one of the containers 8 is flowing and where they are flowing in the conveyance apparatus 7. Therefore, when a container 8 is advancing to an arbitrary treatment apparatus 5-t or 5-s (to be described later), the conveyance apparatus 7 is controlled so that the container 8 moves to the branch conveyance path 22 closest to that treatment apparatus. It is also possible to let the plural containers 8 stand by in each branch conveyance path 22.

When each of the branch conveyance paths 22 receives a container 8 from the associated conveyance apparatus unit 7a (7b), the direction of the container 8 is turned by 90° . Then the container 8 is received by a holding portion 10 of a transfer apparatus 20 to be described later which stands by there, and is thereby transferred onto a container table of an interface device 6-t of a treatment apparatus 5-t (1≦t≦u) belonging to a treatment apparatus group 4-2 or an interface device 6-s of a treatment apparatus 5-s (1≦s≦u) belonging to a treatment apparatus group 4-3. Each of interface devices 6-1, 6-2, 6-3, . . . is provided with two container tables.

The two transfer apparatuses 20 are provided so as to be capable of moving freely in a vertical plane along the conveyance apparatus unit 7a and also in a vertical plane along the conveyance apparatus unit 7b in the upper ceiling space within the clean room. The container tables of the interface devices 6-1, 6-2, 6-3, . . . arranged regularly on the right and left sides of the passage 23 lie approximately below movement paths of the transfer devices 20.

Each transfer device 20 comprises two transfer apparatus units 20a and 20b having different travel ranges from each other. Each of the two transfer apparatus units 20a and 20b travel along each guide rail 21 which is horizontally laid in the upper ceiling portion within the clean room, with approximately a half length of the guide rail as a travel range, and transfer the containers 8 received on the branch conveyance paths 22 onto the container table of the interface device 6-s of the predetermined treatment apparatus 5-s belonging to the treatment apparatus group 4-3 and also onto the container table of the interface device 6-t of the predetermined treatment apparatus 5-t belonging to the treatment apparatus group 4-2.

Each of the transfer apparatuses 20 is provided with a traveling member sliding on the associated guide rail 21, a lift means 12 attached to the traveling member, and a holding portion 10 attached rotatably to the lower end of the lift means 12 to hold containers 8. The holding portion 10 has an inverted U-shaped holding finger, thereby the containers 8 can be held and oriented in an arbitrary direction. When each transfer apparatus 20 receives the containers 8 transferred onto the branch conveyance path 22, the inverted U-shaped holding finger of the holding portion 10 stands by while orienting an inner space surrounded by the U shape toward the container 8. The lift means 12 is constituted by an extension/retraction arm mechanism comprising three pivotable arms.

Various other methods are conceivable as methods for allowing the holding portion 10 of each transfer apparatus 20 to hold the containers 8. For example, at the time of transferring the containers 8 from the conveyance apparatus unit 7a (7b) onto the branch conveyance path 22, the container 8 is transferred onto the branch conveyance path 22 while retaining the posture of the container, then the holding portion 10 of the transfer apparatus 20 is moved in the traveling direction, and the container 8 is held by the inverted U-shaped holding finger of the holding portion 10 which has been brought into a predetermined rotational position (a rotational position where the inverted U-shaped holding finger of the holding portion 10 can hold the container 8). Further, for example in the case where a sufficient vertical spacing is ensured between each transfer apparatus 20 with the lift means 12 in a folded state and each conveyance apparatus unit 7a (7b), the containers, 8 which has been transferred onto a branch conveyance path 22 while keeping its posture unchanged can be held by the holding portion 10 of the transfer apparatus 20 from above the container. In both cases, the conveyance apparatus units 7a and 7b need not be provided with a direction switching mechanism for allowing the direction of each container 8 to match the direction of a load port (interface device).

As noted earlier, the container conveying system of this third embodiment is made up of the conveyance apparatus 7, the transfer apparatuses 20, the branch conveyance paths 22, and the shift mechanisms 24. The branch conveyance paths 22 are not always necessary. Even without using them, a direct conveyance of the containers 8 by the transfer apparatuses 20 from the conveyance apparatus 7 to the treatment apparatuses 5-1, 5-2, 5-3, . . . can be done by driving the conveyance apparatus 7 intermittently.

Since the container conveying system of this embodiment 3 is constructed as above, the following effects can be obtained.

The container conveying system is provided with the conveyance apparatus 7 and the transfer apparatus 20 in the upper ceiling space within the clean room. The conveyance apparatus 7 conveys the containers 8 up to a predetermined position (a position where a predetermined branch conveyance path 22 lies or a position above the position where the predetermined treatment apparatus 5-s or 5-t lies) along the treatment apparatuses 5-1, 5-2, 5-3, . . . arranged on both sides of the passage 23. Each of the transfer apparatuses 20 moves in a vertical plane along the conveyance apparatus 7 in the upper ceiling space within the clean room which covers the area where the treatment apparatuses 5-1, 5-2, 5-3, . . . are disposed, and transfers and delivers the containers 8 between the conveyance apparatus 7 and the treatment apparatuses 5-1, 5-2, 5-3, . . . or between the treatment apparatuses 5-1, 5-2, 5-3, . . . through or without through the branch conveyance path 22.

Thus, the container conveying system includes the conveyance apparatus 7 moving along the treatment apparatuses 5-1, 5-2, 5-3, . . . in the upper ceiling space within the clean room and taking charge of conveyance of the containers 8 and the transfer apparatuses 20 moving along the conveyance apparatus 7 in the upper ceiling space within the clean room and taking charge of the delivery and receipt of the containers 8. Since the respective functions are thus separated from each other, various effects can be obtained as will be described below.

First, a part of the conveyance so far taken charge of by the transfer apparatuses 20 can be taken charge of by the conveyance apparatus 7, and by cooperation of both conveyance means (the conveyance apparatus 7 and the transfer apparatuses 20) the containers 8 can be conveyed and transferred freely to the treatment apparatuses 5-1, 5-2, 5-3, . . . arranged along the conveyance and transfer direction of both conveyance means through or without through the branch conveyance paths 22. Therefore, the conveyance capacity for the containers 8 can be greatly improved as a whole.

Besides, even during operation of the transfer apparatuses 20, the containers 8 can be conveyed by the conveyance apparatus 7 and it is possible to let the container conveyance time and the container transfer time overlap each other, so that the treatment capacity for the containers 8 can be greatly improved.

Moreover, since the plural containers 8 can be placed on the conveyance apparatus 7 and the plural containers 8 lying in plural (U) places on the conveyance apparatus 7 can be delivered to plural (U) treatment apparatuses, the degree of freedom of container conveyance to the plural treatment apparatuses 5-1, 5-2, 5-3, . . . can be improved from a 1:U relation to a U:U relation.

Further, since the conveyance apparatus 7 and the transfer apparatuses 20 are adjacently arranged in parallel with each other in the upper ceiling space within the clean room and the conveyance and transfer of the containers 8 are performed by cooperation of those conveyance and transfer apparatuses, the treatment capacity for the containers 8 can be improved without increasing the foot print of the container conveying system. A space for the clean room can be largely saved by utilizing an internal space of the clean room effectively while utilizing the space below the conveyance apparatus 7 as the passage 23 for workers. Thus, it is possible to reduce the equipment cost and the maintenance cost of the clean room.

Since the plural containers 8 can be placed and stocked on the conveyance apparatus 7, the stock function and the stand-by function of the container conveying system are expanded and the storage capacity of the intermediate stocker disposed between processes can be diminished.

Since the plural containers 8 can be placed on the conveyance apparatus 7 and each transfer apparatus 20 can hold any one of the containers 8 and deliver the container to a predetermined treatment apparatus, the plural containers 8 lying on the conveyance apparatus 7 can be made objects of delivery and it is possible to let the conveyance apparatus 7 have a sorting function.

Since the containers 8 received by the branch conveyance paths 22 can stand by in a standstill state on the branch conveyance paths 22 until the containers 8 are conveyed to the interface devices 6-s and 6-t of the predetermined treatment apparatuses 5-s and 5-t by the transfer apparatuses 20, the containers 8 do not need to stand by on the conveyance apparatus 7 for transfer onto the transfer apparatuses 20, whereby the containers 8 do not cause any obstacle to the conveyance of other containers 8 performed by the conveyance apparatus 7 during the stand-by. Consequently, the treatment capacity for the containers 8 can be further improved as a whole.

The treatment apparatuses 5-1, 5-2, 5-3, . . . are arranged on both sides of the passage 23, the conveyance apparatus 7 is provided with two conveyance apparatus units 7a and 7b traveling respectively along two conveyance paths which are a going path and a returning path, and the transfer apparatuses 20 are disposed on both sides of the conveyance apparatus 7. Therefore, while ensuring the passage 23 for workers centrally, both conveyance means (the conveyance apparatus 7 and the transfer apparatuses 20) are arranged symmetrically and concentratively in the upper ceiling space, whereby the conveyance of the containers 8 to the treatment apparatuses 5-1, 5-2, 5-3, . . . on both sides of the passage 23 can be taken charge of by both conveyance means (the conveyance apparatus 7 and the transfer apparatuses 20) located on both sides. Thus, it is possible to utilize the space effectively and improve the treatment capacity for the containers 8 to a greater extent.

Since the conveyance apparatus 7 is provided with two conveyance apparatus units 7a and 7b traveling respectively along two conveyance paths which are the going path and the returning path, it becomes possible to place a larger number of containers 8 on the conveyance apparatus 7 and hence possible to further expand the stock function, the stand-by function and the sorting function of the container conveying system.

Further, since the two conveyance paths are arranged on the right and left sides in parallel, the structure of the conveyance apparatus 7 including the shift mechanisms 24 which connect the two conveyance apparatus units 7a and 7b traveling along the two going and returning conveyance paths can be simplified.

Thus, the container conveying system of this third embodiment can attain various effects.

A container conveying system according to a still further embodiment (fourth embodiment) of the present invention will be described below.

In this fourth embodiment, two conveyance paths for travel of two conveyance apparatus units 7a and 7b provided in a conveyance apparatus 7 are arranged vertically in parallel. Plural branch conveyance paths 22 are branched from the upper and lower conveyance apparatus units 7a and 7b at appropriate intervals in the conveyance direction so as not to vertically overlap each other. Since the plural branch conveyance paths 22 are provided so as not to vertically overlap each other, transfer apparatuses 20 can take out containers 8 from both conveyance apparatus units.

As a result of the two conveyance paths being arranged vertically in parallel, the width of the passage 23 is made narrower by an amount corresponding to one conveyance apparatus unit.

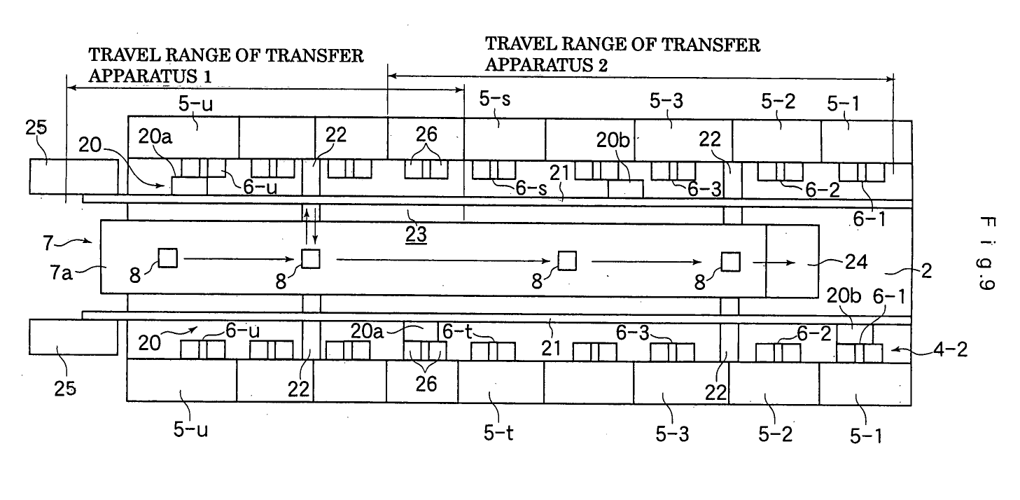

A shift mechanism 24 which connects the upper and lower conveyance apparatus units 7a and 7b is provided on one end side (the right end side in FIG. 9) of both conveyance apparatus units 7a and 7b. The shift mechanism 24 places thereon the container 8 which has reached there after flowing on the upper conveyance apparatus unit 7a like arrows in FIG. 6, then moves down while inverting the direction of the container, and shifts the container 8 onto the lower conveyance apparatus unit 7b. On the other end side (the left end side in FIG. 9) of both conveyance apparatus units 7a and 7b there are provided container tables 25 for the delivery and receipt of the containers 8 between them and other areas.

Each transfer device 20 comprises at least two transfer apparatus units 20a and 20b. The travel range of the transfer apparatus unit 20a and that of the transfer apparatus unit 20b are substantially different from each other. At a portion common to the two units, for the delivery of the container 8 from one transfer apparatus unit to the other, plural delivery tables 26 are provided at a predetermined height position between adjacent interface devices located nearly centrally in the longitudinal direction of the passage 23 apart from the branch conveyance paths 22.

This fourth embodiment is different in the above points from the previous third embodiment, but is the same in other points, and therefore a detailed description will here be omitted.

Since the container conveying system of this fourth embodiment is constructed as above, the following effects can be obtained.

Since the two conveyance paths are arranged vertically in parallel, the two conveyance apparatus units 7a and 7b traveling respectively along the two going and returning conveyance paths are arranged as one above the other and are assembled three-dimensionally. As a result, the space between the treatment apparatuses 5-1, 5-2, 5-3, . . . arranged on both sides of the passage 23 becomes narrower and hence the passage 23 for workers becomes somewhat narrower. As a whole, however, it is possible to save the space to a minimum and further reduce the equipment cost and the maintenance cost of the clean room.

Although in the above third and fourth embodiments, the treatment apparatuses 5-1, 5-2, 5-3, . . . are arranged on both sides of the passage 23 and accordingly the transfer apparatuses 20 are arranged on the right and left sides of the conveyance apparatus 7 (the conveyance apparatus units 7a and 7b) in the ceiling space above the treatment apparatuses 5-1, 5-2, 5-3, . . . on both sides, no limitation is imposed on the arrangement of the treatment apparatuses and the transfer apparatuses. For example, a modification may be made such that the plural treatment apparatuses 5-1, 5-2, 5-3, . . . are arranged on only one side of the passage 23 and accordingly the transfer apparatus 20 is provided on only one side of the conveyance apparatus 7 (the conveyance apparatus units 7a and 7b) in the ceiling space above the treatment apparatuses 5-1, 5-2, 5-3, . . .

Further, although in the above third and fourth embodiments the plural branch conveyance paths 22 are provided in the left and right conveyance apparatus units 7a and 7b at appropriate intervals in the conveyance direction so as to protrude outwards, no limitation is imposed on the branch conveyance paths. The branch conveyance paths 22 need not always be provided.

The present invention is not limited to the above first to fourth embodiments, but various changes may be made within the scope not departing from the gist of the invention.

1. A container conveying system for conveying containers containing substrates such as wafers and reticles within a clean room, said container conveying system comprising:
a conveyance apparatus disposed substantially in parallel with a plurality of treatment apparatuses to convey said containers; and
a transfer apparatus capable of moving freely in an upper ceiling space within said clean room,
said plural treatment apparatuses being arranged on at least one side of a passage and respectively provided with interface devices on the side facing said passage,
said interface devices capable of temporarily receiving said containers and moving said substrates from the interiors of said containers to the interiors of said treatment apparatuses and vice versa in a hermetically sealed atmosphere, and
said transfer apparatus delivering and receiving said containers between said conveyance apparatus and said treatment apparatuses or between said treatment apparatuses.

2. The container conveying system according to claim 1, wherein said conveyance apparatus has a plurality of conveyance paths and conveyance apparatus units capable of independently traveling along each of said conveyance paths.

3. The container conveying system according to claim 2, wherein said plural conveyance paths are arranged vertically in parallel.

4. The container conveying system according to claim 2, wherein said plural conveyance paths are arranged transversely in parallel.

5. The container conveying system according to claim 2, wherein each of said conveyance apparatus units is constituted by a conveyor.

6. The container conveying system according to claim 1, wherein said transfer apparatus comprises at least two transfer apparatus units.

7. A container conveying system for conveying containers containing substrates such as wafers and reticles within a clean room, said container conveying system comprising:
a conveyance apparatus disposed substantially in parallel with a plurality of treatment apparatuses in an upper ceiling space within said clean room to convey said containers; and
a transfer apparatus capable of moving freely in a vertical plane extending along said conveyance apparatus in said upper ceiling space within said clean room,
said plural treatment apparatuses arranged on at least one side of a passage and respectively provided with interface devices on the side facing said passage,
said interface devices capable of temporarily receiving said containers and moving said substrates from the interiors of said containers to the interiors of said treatment apparatuses and vice versa in a hermetically sealed atmosphere, and
said transfer apparatus delivering and receiving said containers between said conveyance apparatus and said treatment apparatuses or between said treatment apparatuses.

8. The container conveying system according to claim 7, wherein a plurality of branch conveyance paths are provided at appropriate intervals in the conveyance direction of said conveyance apparatus, said plural branch conveyance paths designed for receiving said containers having been conveyed by said conveying apparatus and allowing the containers to stand by; and
said transfer apparatus holds said containers standing by on said plural branch conveyance paths and delivers the containers to any of said plural treatment apparatuses.

9. The container conveying system according to claim 7, wherein said plural treatment apparatuses are arranged on both sides of said passage,
said conveyance apparatus has two conveyance apparatus units traveling respectively along two conveyance paths which are a going path and a returning path, and
said transfer apparatus is provided on the right and left sides of said conveyance apparatus.

10. The container conveying system according to claim 9, wherein said two conveyance paths are arranged transversely in parallel.

11. The container conveying system according to claim 9, wherein said two conveyance paths are arranged vertically in parallel.

12. The container conveying system according to claim 3, wherein each of said conveyance apparatus units is constituted by a conveyor.

13. The container conveying system according to claim 4, wherein each of said conveyance apparatus units is constituted by a conveyor.

14. The container conveying system according to claim 2, wherein said transfer apparatus comprises at least two transfer apparatus units.

15. The container conveying system according to claim 3, wherein said transfer apparatus comprises at least two transfer apparatus units. 14.

16. The container conveying system according to claim 4, wherein said transfer apparatus comprises at least two transfer apparatus units.

17. The container conveying system according to claim 5, wherein said transfer apparatus comprises at least two transfer apparatus units.

18. The container conveying system according to claim 8, wherein said plural treatment apparatuses are arranged on both sides of said passage,
said conveyance apparatus has two conveyance apparatus units traveling respectively along two conveyance paths which are a going path and a returning path, and
said transfer apparatus is provided on the right and left sides of said conveyance apparatus.
